(19) United States
(12) Patent Application Publication
(10) Pub. No.: US 2014/0170565 A1
(43) Pub. Date: Jun. 19, 2014

(54) PATTERN FORMING METHOD AND METHOD FOR MANUFACTURING TEMPLATE FOR IMPRINT

(71) Applicant: Kabushiki Kaisha Toshiba, Tokyo (JP)

(72) Inventor: Shingo KANAMITSU, Kawasaki-shi (JP)

(73) Assignee: KABUSHIKI KAISHA TOSHIBA, Tokyo (JP)

(21) Appl. No.: 13/948,855

(22) Filed: Jul. 23, 2013

(30) Foreign Application Priority Data
Dec. 13, 2012 (JP) 2012-272678

(51) Int. Cl. G03F 7/20

(52) U.S. Cl. CPC G03F 7/20
USPC 430/296

(57) ABSTRACT

In one embodiment, a pattern forming method includes irradiating a predetermined region of a mask member, provided on a substrate, with an ion beam to inject ions, forming a self-assembled material layer having a first polymer and a second polymer on the mask member, microphase-separating the self-assembled material layer, to form first polymer section containing the first polymer and second polymer section containing the second polymer, the second polymer section being provided on the predetermined regions, removing one of the first polymer section and the second polymer section and transferring a pattern shape of the other to the mask member, and processing the substrate with the mask member used as a mask.

### CROSS REFERENCE TO RELATED APPLICATION

This application is based upon and claims benefit of priority from the Japanese Patent Application No. 2012-272678, filed on Dec. 13, 2012, the entire contents of which are incorporated herein by reference.

Embodiments described herein relate generally to a pattern forming method and a method for manufacturing a template for imprint.

### BACKGROUND

As a technique for forming a fine pattern at low cost, a photo nanoimprint method is known. This is a method where a template having concavities and convexities corresponding to a pattern that is wished to be formed on a substrate is pressed onto a photo-curable organic material layer applied to the substrate surface, and irradiated with light to cure the organic material layer, and the template is then released from the organic material layer, thereby to transfer the pattern.

The template includes a master template to serve as an original and a replica template made of a copy of the master template. The replica template is used at the time of transferring a pattern onto a wafer for semiconductor device manufacturing, and it is replaced by another replica template when deterioration such as abrasion or contamination with a dust occurs.

A pattern with the same pitch as that of the pattern to be formed on the wafer is formed on the master template by electron beam drawing. A primary beam that is incident on the template substrate can be reduced to about 1 to 3 nm. However, even by use of such a fine beam, backscatter electrons radiated from the substrate in the opposite direction to the incident direction expand in the range of several tens of nm, to expose a resist to light. This leads to the same state as a state where the beam apparently blurs, where it is not possible to obtain a sufficient resolution for resolving a fine pattern, especially a pattern with a half pitch of not larger than 20 nm.

### BRIEF DESCRIPTION OF THE DRAWINGS

FIG. 1 is a schematic constitutional view of a focused ion beam device;

FIG. 2 is a schematic constitutional view of an ion source section of the focused ion beam device;

FIG. 3 is a process sectional view explaining a pattern forming method according to a present embodiment;

FIG. 4A is a top view explaining the pattern forming method;

FIG. 4B is a process sectional view subsequent to FIG. 3;

FIG. 5 is a process sectional view subsequent to FIG. 4;

FIG. 6A is a top view explaining the pattern forming method;

FIG. 6B is a process sectional view subsequent to FIG. 5;

FIG. 7 is a process sectional view subsequent to FIG. 6B;

FIG. 8 is a process sectional view subsequent to FIG. 7;

FIG. 9 is a process sectional view subsequent to FIG. 8; and

FIG. 10 is a process sectional view subsequent to FIG. 9.

### DETAILED DESCRIPTION

In one embodiment, a pattern forming method includes irradiating a predetermined region of a mask member, provided on a substrate, with an ion beam to inject ions, forming a self-assembled material layer having a first polymer and a second polymer on the mask member, microphase-separating the self-assembled material layer, to form first polymer section containing the first polymer and second polymer section containing the second polymer, the second polymer section being provided on the predetermined regions, removing one of the first polymer section and the second polymer section and transferring a pattern shape of the other to the mask member, and processing the substrate with the mask member used as a mask.

Embodiments will now be explained with reference to the accompanying drawings.

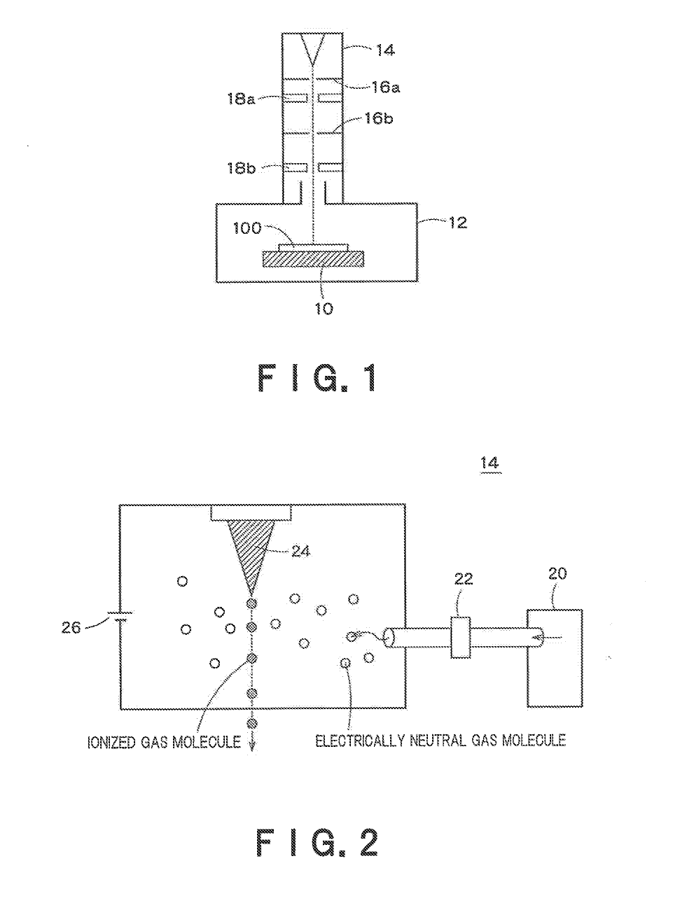

FIG. 1 shows a schematic configuration of a focused ion beam device to be used in a pattern forming method according to the present embodiment. As shown in FIG. 1, the focused ion beam device is provided with a stage 10 on which a substrate 100 is mounted and that is movable in a horizontal direction, a vacuum chamber 12 that houses the stage 10, and an ion source section 14 that irradiates the substrate 100 with an ion beam. Between the ion source section 14 and the vacuum chamber 12 provided are apertures 16a, 16b that reduce a beam diameter, lenses (a focus lens 18a and an objective lens 18b) that finely form the beam, a blanking unit (not shown) that performs blanking on the beam, and the like, and the diameter of the beam emitted from the ion source section 14 can be reduced to the about 3 nm. Performing irradiation with the beam while moving the stage 10 based on pattern data allows drawing of the desired pattern on the substrate 100.

FIG. 2 shows a schematic configuration of the ion source section 14. The ion source section 14 has a field ionization-type ion source (GFIS: Gas Field Ion Source), and when electrically neutral gas molecules supplied from a gas cylinder 20 come near a cooling head 24, to which an intense electric field is applied by a high-pressure power source 26, electrons inside the gas molecules tunnel through a potential barrier reduced by the electric field, thereby to become positive ions (ionized gas molecules) and then be released. These released ionized gas molecules are used as an ion beam. The cooling head 24 has a needle-like metal, and since an extremely narrow range of the tip of the needle-like metal surface becomes an ionization region, an energy width of the ion beam is small, and the beam can be finely reduced. A gas supply from the gas cylinder 20 is controlled by a flow rate controller 22.

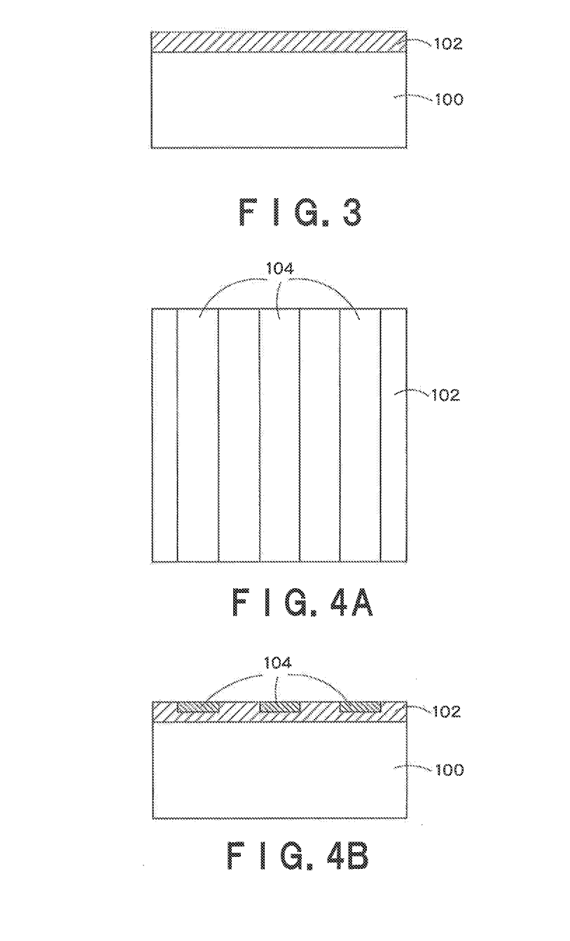

A pattern forming method according to the present embodiment will be described using FIGS. 3 to 10. It is to be noted that FIGS. 3, 4B, 5, 6B and 7 to 10 are sectional views, and FIGS. 4A and 6A are top views.

First, as shown in FIG. 3, the substrate 100 with a chromium film 102 formed on its surface is prepared. For example, the substrate 100 is a quartz substrate with its one side being 6 inch long, and the chromium film 102 has a film thickness of about 3 nm.

Next, the substrate 100 is carried to the vacuum chamber 12 of the focused ion beam device shown in FIG, 1, to be subjected to positioning such as centering or rotation, and then it is irradiated with the ion beam, to inject ions into a predetermined region of the chromium film 102. The ions are injected into the surface portion of the chromium film 102, to form an ion injection region. For example, a plurality of line-shaped ion injection regions 104 each having a width of 10 nm are formed at intervals of 10 nm as shown in FIGS. 4A and 4B.

Here, as an ionic species to be injected into the chromium film 102, there is used one capable of surface-reforming (surface-modifying) the chromium film 102 that shows hydrophobic properties, to make it have hydrophilic properties. For example, injecting water cluster ions into the chromium film 102 can make the ion injection region 104 hydrophilic. Further, when irradiation is performed with ions at relatively low energy (several KeV), the ions stay only in a surface portion of the chromium film 102, and that portion can be efficiently made hydrophilic.

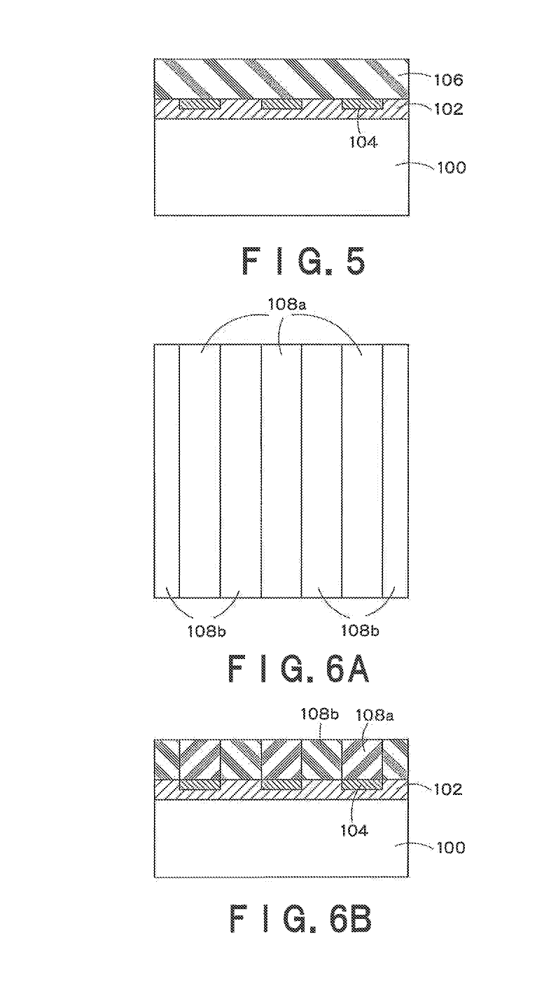

Next, as shown in FIG. 5, a block copolymer is applied onto the chromium film 102, to form a self-assembled material layer 106. As the block copolymer, for example, a random copolymer of polystyrene (PS) and polymethyl methacrylate (PMMA) is used. The block copolymer used here is one molecularly designed in accordance with the shape of the ion injection region 104 such that PS and PMMA each have a length of about 10 nm.

Subsequently, as shown in FIGS. 6A and 6B, the substrate 100 with the self-assembled material layer 106 formed thereon is heated at 230° C. for several minutes. Thereby, the block copolymer of the self-assembled material layer 106 is microphase-separated, to form a pattern including a first polymer section 108a containing a first polymer block chain and a second polymer section 108b containing a second polymer block chain. For example, the first polymer section 108a containing PMMA that shows hydrophilic properties is formed on the ion injection region 104, and the second polymer section 108b containing PS is formed on a region not injected with the ions of the chromium film 102. That is, the ion injection region 104 functions as a chemical guide for aligning the polymers.

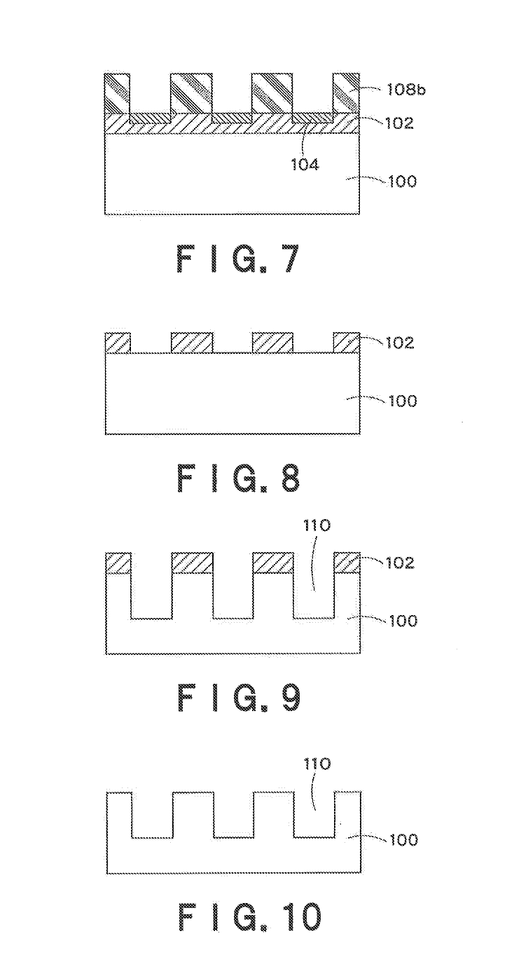

Next, as shown in FIG. 7, by wet etching using an organic solvent, the second polymer section 108b is made to remain and the first polymer section 108a is selectively removed.

Subsequently, as shown in FIG. 8, using as a mask the second polymer sections (PS) 108b having been made to remain, the chromium film 102 is processed by dry etching by use of chlorine gas. Thereafter, the second polymer section 108b is removed.

Next, as shown in FIG. 9, using the chromium film 102 as a hard mask, the substrate 100 is processed by dry etching, to form a trench 110.

Next, as shown in FIG. 10, by removing the chromium film 102, the substrate 100 that has a structure of trenches each having a width of 10 nm corresponding to the ion injection region 104 can be obtained. This substrate 100 becomes a template to be used, for example, in an imprint process.

In the present embodiment, by ion injection using the focused ion beam device, the hard mask (chromium film 102) is separated into the hydrophilic region and the hydrophobic region in a fine and accurate manner, and using these as the chemical guide, the block copolymer is microphase-separated, to form the self-assembled pattern. Then, the hard mask is processed using the self-assembled pattern as a mask, and the substrate 100 is processed using this hard mask. Hence, it is possible to form an extremely fine pattern on the substrate 100.

The chromium film 102, which in the above embodiment is used as a hard mask, may be substituted by a chrome oxide film. In this case, as the ions to be injected by the focused ion beam device, hydrogen ions are preferably used. Injecting the hydrogen ions leads to generation of an OH group on the surface of the chrome oxide film, and the ion injection region can thus be made hydrophilic.

Further, a neutralized film may be applied onto the hard mask and ions may be injected into this neutralized film, to form the hydrophilic region or the hydrophobic region. As the ionic species, water or hydrogen can be used in the case of forming the hydrophilic region, and fluorine or silicon can be used in the case of forming the hydrophobic region.

In the above embodiment, a length of a molecule of at least one of a first polymer block and a second polymer block that are contained in the block copolymer is preferably designed to be equivalent to a width of the ion injection region 104 or the ion non-injection region.

With the pattern forming method according to the above embodiment, it is possible to facilitate formation of a fine pattern which has a half pitch of not larger than 20 nm and whose sufficient resolution cannot be obtained by electron beam drawing.

Although a plurality of line-shaped ion injection regions 104 have been formed in the above embodiment, the shape of the ion injection region 104 is not restricted to the line shape, but can be one corresponding to the shape of the pattern to be processed on the substrate 100.

Although the self-assembled material layer 106 is formed using PS-PMMA (polystyrene-polymethyl methacrylate) in the above embodiment, another material may be used such as PS-PDMS (polystyrene-dimethylpolysiloxane), PS-PEO (polystyrene-polyethylene oxide) or PS-PHOST (polystyrene-polyhydroxystyrene).

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A pattern forming method, comprising:
irradiating a predetermined region of a mask member, provided on a substrate, with an ion beam to inject ions;
forming a self-assembled material layer having a first polymer and a second polymer on the mask member;
microphase-separating the self-assembled material layer, to form first polymer section containing the first polymer and second polymer section containing the second polymer, the second polymer section being provided on the predetermined regions;
removing one of the first polymer section and the second polymer section and transferring a pattern shape of the other to the mask member; and
processing the substrate with the mask member used as a mask.

2. The pattern forming method according to claim 1, wherein the mask member is hydrophobic and the region injected with the ions becomes hydrophilic.

3. The pattern forming method according to claim 2, wherein the mask member is a chromium film, and water cluster ions are injected into the predetermined region.

4. The pattern forming method according to claim 2, wherein the mask member is a chrome oxide film, and hydrogen is injected into the predetermined region.

5. The pattern forming method according to claim 1, wherein the predetermined region includes a plurality of line shapes.

6. The pattern forming method according to claim 5, wherein a half pitch of the plurality of line shapes is not larger than 20 nm.

7. The pattern forming method according to claim 5, wherein a length of a molecule of the first polymer or the second polymer corresponds to a width of the line shape or a width of an interval between the lines.

8. The pattern forming method according to claim 7, wherein the first polymer is polystyrene, and the second polymer is polymethyl methacrylate.

9. The pattern forming method according to claim 1, wherein irradiation is performed with the ion beam using a focused ion beam device.

10. The pattern forming method according to claim 1, wherein the mask member has a hard mask, and a neutralized film provided on the hard mask.

11. A method for manufacturing a template for imprint, comprising:
irradiating a predetermined region of a mask member, provided on a quartz substrate, with an ion beam to inject ions;
forming a self-assembled material layer having a first polymer and a second polymer on the mask member;
microphase-separating the self-assembled material layer, to form first polymer section containing the first polymer and second polymer section containing the second polymer, the second polymer section being provided on the predetermined regions;
removing one of the first polymer section and the second polymer section and transferring a pattern shape of the other to the mask member; and
processing the quartz substrate with the mask member used as a mask.

12. The method for manufacturing a template for imprint according to claim 11, wherein the mask member is hydrophobic and the region injected with the ions becomes hydrophilic.

13. The method for manufacturing a template for imprint according to claim 12, wherein the mask member is a chromium film, and water cluster ions are injected into the predetermined region.

14. The method for manufacturing a template for imprint according to claim 12, wherein the mask member is a chrome oxide film, and hydrogen is injected into the predetermined region.

15. The method for manufacturing a template for imprint according to claim 11, wherein the predetermined region includes a plurality of line shapes.

16. The method for manufacturing a template for imprint according to claim 15, wherein a half pitch of the plurality of line shapes is not larger than 20 nm.

17. The method for manufacturing a template for imprint according to claim 15, wherein a length of a molecule of the first polymer or the second polymer corresponds to a width of the line shape or a width of an interval between the lines.

18. The method for manufacturing a template for imprint according to claim 17, wherein the first polymer is polystyrene, and the second polymer is polymethyl methacrylate.

19. The method for manufacturing a template for imprint according to claim 11, wherein irradiation is performed with the ion beam using a focused ion beam device.

20. The method for manufacturing a template for imprint according to claim 11, wherein the mask member has a hard mask, and a neutralized film provided on the hard mask.
